(19) United States
(12) Patent Application Publication
(10) Pub. No.: US 2009/0052147 A1
(43) Pub. Date: Feb. 26, 2009

(54) Standoff

(75) Inventor: Tzu-Wen Sung, Taipei City (TW)

Correspondence Address: Joe McKinney Muncy, PO Box 1364, Fairfax, VA, 22038-1364, US

(73) Assignee: INVENTEC CORPORATION

(21) Appl. No.: 11/892,117

(22) Filed: Aug. 20, 2007

(51) Int. Cl. H05K 13/04; H05K 7/00

(52) U.S. Cl. 361/752

(57) ABSTRACT

A standoff includes a supporter, an elastic arm, a pin and a fixing part. The supporter supports the first surface of a first substrate. The elastic arm is located apart from the supporter, and this elastic arm is inserted into a fixing hole of the first substrate. The pin is connected to the elastic arm to press a second surface of the first substrate opposite to the first surface of the first substrate. The fixing part connects the supporter and the elastic arm, and this fixing part is fixed on a second substrate.

### BACKGROUND

1. Field of Invention

The present invention relates to a computer system. More particularly, the present invention relates to a standoff of a computer system.

2. Description of Related Art

With the fast development of the electronics industry and information technology, the application of information products has become more popular. For example, personal computers and the computer servers are commonly used devices. Accordingly, computer manufacturers conscientiously work to find every possible means for fixing printed circuit boards (PCB) to maintain the normal operation of a computer system. On the other hand, computer manufacturers also look forward to an easier and faster way to fix the PCB to provide an efficient repair process and an efficient installation process for the computer system.

### SUMMARY

One object of the present invention is to provide a standoff to fix a PCB on a computer system.

To achieve these and other advantages and in accordance with the purpose of the present invention, as the embodiment broadly describes herein, the present invention provides a standoff including a supporter, an elastic arm, a pin and a fixing part. The supporter is coupled to a first surface of a first substrate. The elastic arm is disposed apart from the supporter a predetermined distance, and the elastic arm is inserted into a fixing hole of the first substrate. The pin is connected to the elastic arm to couple to a second surface, opposite to the first surface, of the first substrate. The fixing part is connected to the supporter and the elastic arm. The fixing part is fixed on a second substrate.

Another aspect of the present invention is to provide a standoff including a fixing part, a supporter, an elastic arm and a pin. The supporter is coupled to one end of the fixing part and the elastic arm is coupled to another end of the fixing part. The supporter and the elastic arm are both extended in the same direction away from the fixing part. The pin is connected to the elastic arm. In addition, the vertical gap between a bottom surface, close to the fixing part, of the pin and a top surface, far away from the fixing part, of the supporter is about a thickness of a print circuit board.

Accordingly, the standoff of the present invention can effectively fix a first substrate on a second substrate at a predetermined height.

It is to be understood that both the foregoing general description and the following detailed description are by examples, and are intended to provide further explanations of the invention as claimed.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a schematic view of the standoff according to one preferred embodiment of this invention;

FIG. 2 is a perspective view of the standoff according to FIG. 1; and

FIG. 3 is a top view of the first substrate according to FIG. 1.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

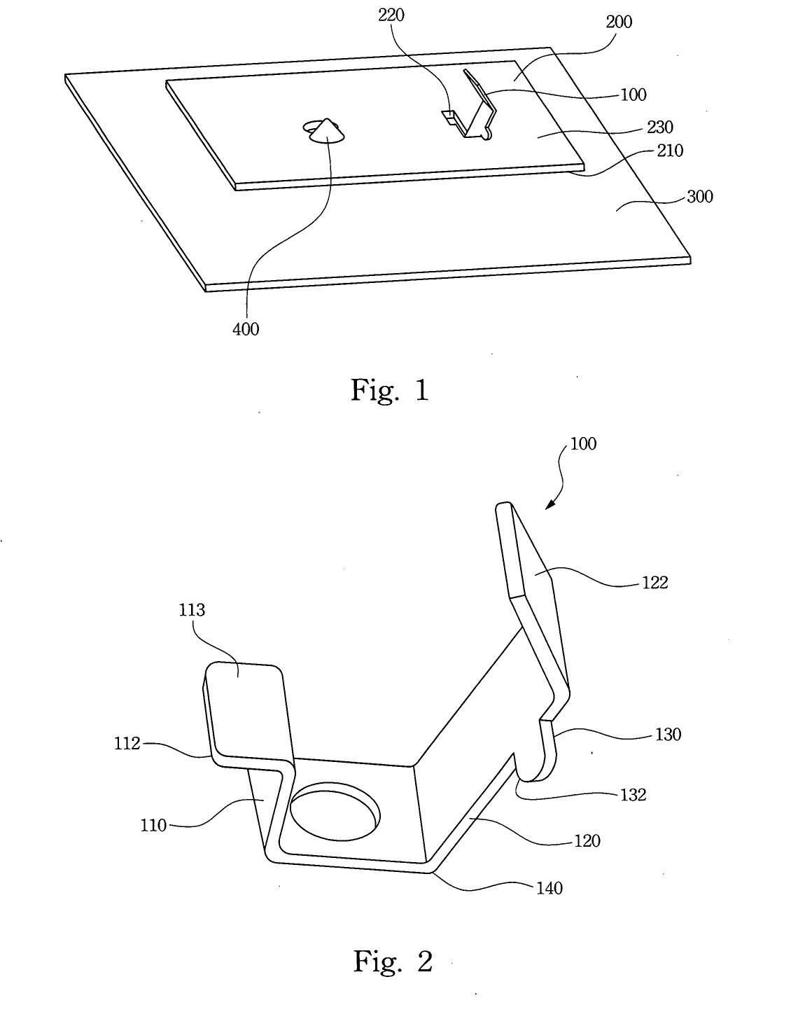

FIG. 1 is a schematic view of a standoff 100 according to one preferred embodiment of this invention. FIG. 2 is a perspective view of the standoff 100 according to FIG. 1. The standoff 110 includes a supporter 110, an elastic arm 120, a pin 130 and a fixing part 140. The supporter 110 is coupled to a first surface 210 of a first substrate 200, for example, a print circuit board (PCB). The elastic arm 120 is located apart from the supporter 110 at a predetermined distance, and the elastic arm 120 is inserted into a fixing hole 220 of the first substrate 200. The pin 130 is connected to the elastic arm 120 to hold a second surface 230 of the first substrate 200 opposite to the first surface 210 of the first substrate 200. The fixing part 140 fixed on a second substrate 300 is connected to the supporter 110 and the elastic arm 120.

Referring to FIG. 2, the supporter 110 is connected to one end of the fixing part 140, and the elastic arm 120 is connected to another end of the fixing part 140. Moreover, the supporter 110 and the elastic arm 120 both extend from the fixing part 140 towards the same side, that is to say, towards an upper side of the fixing part 140 of FIG. 2. The pin 130 is connected to one lateral side of the elastic arm 120. A vertical gap between a surface 132 of the pin 130 close to the fixing part 140 and the surface 113 of the supporter 110 is approximately to the same as the thickness of the first substrate 200 of FIG. 1. Therefore, the first substrate 200 can be fixed between the pin 130 and the supporter 110.

Additionally, referring to FIG. 2, the supporter 110, the elastic arm 120, the pin 130 and the fixing part 140 are integrally formed together. More particularly, the material of the elastic arm 120 preferably includes the metal material so as to easily make the standoff 100 with metal working processes. Although the present invention has been described in considerable detail with reference certain preferred embodiments thereof, other embodiments are possible. For example, the material of the elastic arm may include other flexible material. Therefore, the spirit and scope of the appended claims should no be limited to the description of the preferred embodiments container herein.

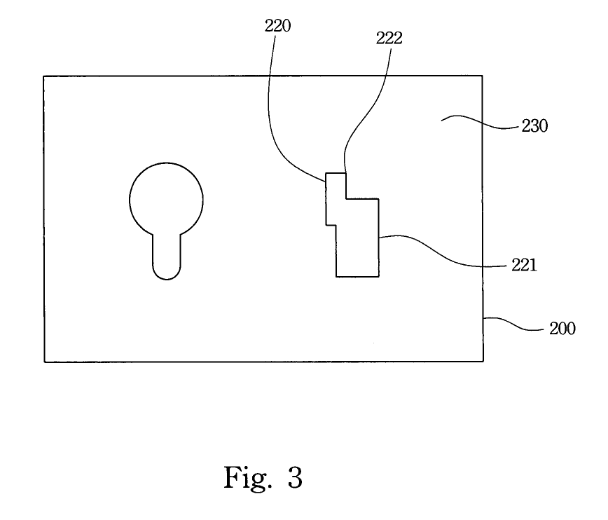

Refer to FIG. 2 and FIG. 3. FIG. 3 is a top view of the first substrate according to FIG. 1. When the first substrate 200 is fixed by the standoff 100, the elastic arm 120 is inserted into an edge 221 of the fixing hole 220 of FIG. 3. That is to say, when a user wants to fix the first substrate 200, the user has to first bend the elastic arm 120 to penetrate the first substrate 200 by way of the opening 222 of the fixing hole 220. Referring to FIG. 3, the length of the opening 222 is larger than the total length of the elastic arm 120 and the pin 300, and therefore the elastic arm 120 can move in the vertical direction of the opening 222 of FIG. 3. Therefore, the elastic arm 120 is aligned to the edge 221 of the fixing hole 220 by pushing the first substrate 200 upwards. The elastic arm 120 couples to the edge 221 of the fixing hole 220 after the user releases the elastic arm 120. In the moment, the pin 130 automatically couples on the second surface 230 of the first substrate 200.

When the elastic arm 120 is inserted into the fixing hole 220, the elastic arm 120 couples to the edge 221 of the fixing hole 220 to restrict the movement of the first substrate 200 in the vertical direction of FIG. 3 by pushing the first substrate 200 upwards. Because the elasticity of the elastic arm 120 and the shape of the fixing hole 220, the first substrate 200 is restricted in the vertical direction of FIG. 3 after the first substrate 200 is moved upwards and the elastic arm 120 couples to the edge 221 of the fixing hole 220.

In combination with a horizontal restriction component, such as the fixing mechanism 400 of FIG. 1, to further restrict the movement of the first substrate 200 in the horizontal direction, the first substrate 200 can effectively be fixed on the second substrate 300.

On the other hand, when the user wants to remove the first substrate 200, the user first bends the elastic arm 120 to escape from the edge 221 of the fixing hole 220, and forces the elastic arm 120 to enter the opening 222 of the fixing hole 220. Subsequently, the first substrate 200 is pushed downwards to allow the first substrate 200 to be released from the standoff 100 after the pin 130 is moved into the opening 222. When the elastic arm 120 is bent, the first substrate 200 is allowed to move in the vertical direction of FIG. 3. After the pin 130 enters into the opening 222 and releases from the second surface 230 of the first substrate 200, the user may remove the first substrate 200 therefrom. Although the present invention has been described in considerable detail with reference certain preferred embodiments thereof, other embodiments are possible. In one embodiment, the fixing hole 220 in FIG. 3 may be formed in other shape.

Additionally, FIG. 2 shows a bending component 112 of the supporter 110 at one end of the fixing part 140. The bending component 112 is bent parallel to the first surface 210 of the first substrate 200 to increase the contact area of the supporter 110 on the first substrate 200 so as to prevent from a stress damage on the first substrate 200. In accordance with one embodiment of the present invention, the bending component 112 is parallel to the fixing part 140. More particularly, an included angle between the bending component 112 and the supporter 110 is about 90 degrees, and an included angle between the supporter 110 and the fixing part 140 is also about 90 degrees.

For the above-mentioned example, an included angle between the bending component 112 and the supporter 110 is about 90 degrees, and an included angle between the supporter 110 and the fixing part 140 is also about 90 degrees. As long as the bending component 112 can smoothly touch the first surface 210 of a first substrate 200, the included angle between the bending component 112 and the supporter 110 may be slightly larger or smaller than 90 degrees, and the included angle between the supporter 110 and the fixing part 140 may also be slightly larger or smaller than 90 degrees.

FIG. 2 shows the gripping component 122 of the elastic arm 120 is disposed at one end of the elastic arm 120 which is far away from the fixing part 140. The gripping component 122 bends toward the supporter 110 to enable the user can conveniently hold the gripping component 122.

In accordance with another preferred embodiment of the present invention, the standoff is not merely used alone but also in combination with a traditional fixing mechanism to fix the first substrate. For example, the standoff 100 is operated with at least one traditional fixing mechanism 400 to fix the first substrate 200.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A standoff, comprising:
a supporter to couple to a first surface of a first substrate;
an elastic arm disposed apart from the supporter a predetermined distance, and the elastic arm inserted into a fixing hole of the first substrate;
a pin connected to the elastic arm to couple to a second surface, opposite to the first surface, of the first substrate; and
a fixing part connected to the supporter and the elastic arm, wherein the fixing part is fixed on a second substrate.

2. The standoff of claim 1, wherein the supporter, the elastic arm, the pin and the fixing part are integrally formed.

3. The standoff of claim 1, wherein the elastic arm comprises a flexible material.

4. The standoff of claim 1, wherein the elastic arm comprises metal.

5. The standoff of claim 1, wherein the supporter further comprises a bending component at one end of the supporter far away from the fixing part.

6. The standoff of claim 5, wherein the bending component is bent parallel to the first surface of the first substrate.

7. The standoff of claim 5, wherein the bending component is parallel to the fixing part.

8. The standoff of claim 5, wherein an included angle between the bending component and the supporter is about 90 degrees, and an included angle between the supporter and the fixing part is about 90 degrees.

9. The standoff of claim 1, wherein the elastic arm further comprises a gripping component at one end of the elastic arm far away from the fixing part.

10. The standoff of claim 9, wherein the gripping component is bent toward the supporter.

11. A standoff, comprising:
a fixing part;
a supporter coupled to one end of the fixing part;
an elastic arm coupled to another end of the fixing part, and the supporter and the elastic arm extended toward a same direction from the fixing part; and
a pin connected to the elastic arm, wherein a vertical gap between a bottom surface, close to the fixing part, of the pin and a top surface, far away from the fixing part, of the supporter is about a thickness of a print circuit board.

12. The standoff of claim 11, wherein the supporter, the elastic arm, the pin and the fixing part are integrally formed.

13. The standoff of claim 11, wherein the elastic arm comprises a flexible material.

14. The standoff of claim 11, wherein the elastic arm comprises metal.

15. The standoff of claim 11, wherein the supporter further comprises a bending component at one end of the supporter far away from the fixing part.

16. The standoff of claim 15, wherein the bending component is bent parallel to the first surface of the first substrate.

17. The standoff of claim 15, wherein the bending component is parallel to the fixing part.

18. The standoff of claim 15, wherein an included angle between the bending component and the supporter is about 90 degrees, and an included angle between the supporter and the fixing part is about 90 degrees.

19. The standoff of claim 11, wherein the elastic arm further comprises a gripping component at one end of the elastic arm far away from the fixing part.

20. The standoff of claim 19, wherein the gripping component is bent toward the supporter.
